(19) United States
(12) Patent Application Publication
(10) Pub. No.: US 2010/0269319 A1
(43) Pub. Date: Oct. 28, 2010

(54) METHOD FOR MANUFACTURING SURFACE ACOUSTIC WAVE DEVICE

(75) Inventors: Masashi OMURA, Ishikawa-gun (JP); Yoshiki RYU, Nagaokakyo-shi (JP); Harunobu HORIKAWA, Kanazawa-shi (JP)

Correspondence Address: MURATA MANUFACTURING COMPANY, LTD.;C/O KEATING & BENNETT, LLP, 1800 Alexander Bell Drive, SUITE 200, Reston, VA, 20191, US

(73) Assignee: MURATA MANUFACTURING CO., LTD., Nagaokakyo-shi (JP)

(21) Appl. No.: 12/767,823

(22) Filed: Apr. 27, 2010

(30) Foreign Application Priority Data
Apr. 28, 2009 (JP) 2009-109832

(51) Int. Cl. H01L 41/22

(52) U.S. Cl. 29/25.35; 310/313 R

(57) ABSTRACT

A method for manufacturing a surface acoustic wave device includes a substrate thickness reduction step of reducing the thickness of a piezoelectric substrate by machining a principal surface of the piezoelectric substrate, and a bonding step of bonding a support substrate having a smaller coefficient of linear expansion than the piezoelectric substrate through a resin adhesive layer to the piezoelectric substrate the thickness of which is reduced.

### BACKGROUND OF THE INVENTION

1. Field of the Invention

The present invention relates to a method for manufacturing a surface acoustic wave device. More particularly, the present invention relates to a method for manufacturing a surface acoustic wave device in which a support substrate is bonded to a piezoelectric substrate.

2. Description of the Related Art

In a surface acoustic wave device which employs surface acoustic waves on a piezoelectric substrate, by bonding a support substrate having a smaller coefficient of linear expansion than the piezoelectric substrate to the piezoelectric substrate, it is possible to reduce a variation in frequency characteristics due to a change in temperature, and to improve temperature characteristics. As described below, various methods have been proposed for manufacturing a surface acoustic wave device in which a support substrate is bonded to a piezoelectric substrate.

FIGS. 4A to 4D are cross-sectional views schematically showing manufacturing steps in a first manufacturing process. As shown in FIG. 4A, a piezoelectric substrate 10 is prepared, and as shown in FIG. 4B, a support substrate 14 is bonded to a back surface 10b of the piezoelectric substrate 10. Next, as shown in FIG. 4C, a front surface 10a of the piezoelectric substrate 10 is machined to reduce the thickness of the piezoelectric substrate 10. Next, as shown in FIG. 4D, a device pattern 20 including interdigital transducer (IDT) electrodes is formed on the front surface 10a of the piezoelectric substrate 10.

For example, Japanese Unexamined Patent Application Publication No. 2005-229455 discloses that a Si substrate is bonded through an adhesive layer to the back surface of a piezoelectric substrate with a thickness of 200 μm, and then the front surface of the piezoelectric substrate is machined so that the thickness of the piezoelectric substrate is 20 μm. In paragraph [0028] of Japanese Unexamined Patent Application Publication No. 2005-229455, it is described that when the thickness of the adhesive layer is smaller than 1.5 μm, bonding strength is insufficient.

Japanese Unexamined Patent Application Publication No. 2007-214902 discloses that a ceramic substrate is bonded through an adhesive layer to the back surface of a piezoelectric substrate, and then the front surface of the piezoelectric substrate is machined to reduce the thickness of the piezoelectric substrate to 20 μm.

FIGS. 5A to 5C are cross-sectional views schematically showing manufacturing steps in a second manufacturing process. As shown in FIG. 5A, a device pattern 20 including IDT electrodes is formed on a front surface 10a of a piezoelectric substrate 10. Then, as shown in FIG. 5B, a back surface 10b of the piezoelectric substrate 10 is machined to reduce the thickness of the piezoelectric substrate 10, and as shown in FIG. 5C, a support substrate 14 is bonded to the back surface 10b of the piezoelectric substrate 10. For example, Japanese Unexamined Patent Application Publication No. 2002-16468 discloses that IDT electrodes, etc., are formed on the front surface of a piezoelectric substrate, the thickness of the piezoelectric substrate is reduced by lapping the back surface of the piezoelectric substrate, and then an insulating substrate is bonded to the back surface of the piezoelectric substrate using a glass layer.

In the case where an insulating substrate is bonded to a piezoelectric substrate using a glass layer as in Japanese Unexamined Patent Application Publication No. 2002-16468, it is necessary to perform bonding at a high temperature. In the wafer state, warpage may occur due to the difference in the coefficient of linear expansion between the piezoelectric substrate and the insulating substrate. Therefore, it is not easy to perform machining with high accuracy. When bonding is performed in the chip state, manufacturing efficiency is low, which is impractical.

In the case where a support substrate is bonded to a piezoelectric substrate, and then the thickness of the piezoelectric substrate is reduced as in Japanese Unexamined Patent Application Publication No. 2005-229455 and Japanese Unexamined Patent Application Publication No. 2007-214902, the piezoelectric substrate is machined while being supported by the support substrate through an adhesive layer, thus easily causing variations in the thickness of the piezoelectric substrate and waviness of the front surface. Therefore, it is not easy to machine the piezoelectric substrate with high accuracy.

### SUMMARY OF THE INVENTION

Accordingly, preferred embodiments of the present invention provide a method for manufacturing a surface acoustic wave device in which the surface acoustic wave device can be easily and efficiently manufactured with high accuracy.

According to a preferred embodiment of the present invention, a method for manufacturing a surface acoustic wave device includes (a) a substrate thickness reduction step of reducing the thickness of a piezoelectric substrate by machining a principal surface of the piezoelectric substrate, and (b) a bonding step of bonding a support substrate having a smaller coefficient of linear expansion than the piezoelectric substrate through a resin adhesive layer to the piezoelectric substrate, the thickness of which is reduced.

According to the method described above, in the substrate thickness reduction step, since the piezoelectric substrate is machined in a state in which the support substrate is not bonded, in comparison with the case where the piezoelectric substrate is machined while being supported by the support substrate through an adhesive layer, variations in the thickness of the piezoelectric substrate and waviness of the front surface are prevented from occurring, and the thickness of the piezoelectric substrate can be reduced by machining with high accuracy. Furthermore, manufacturing can be performed efficiently in the wafer state.

When bonding is performed using a resin adhesive layer, the piezoelectric substrate and the support substrate can be bonded to each other at a lower temperature than the case where bonding is performed using a glass layer, and thus warpage due to heat can be reduced.

Preferably, the method further includes, before the substrate thickness reduction step, a pattern formation step of forming a device pattern including IDT electrodes on another principal surface of the piezoelectric substrate.

In the case where a device pattern is formed on the piezoelectric substrate after the substrate thickness reduction step and the bonding step, if the support substrate is thin, warpage may occur due to the difference in the coefficient of linear expansion between the piezoelectric substrate and the support substrate due to heat during formation of the device pattern on the piezoelectric substrate, thus preventing accurate patterning, and in the worst case, the wafer may be cracked. Consequently, it is necessary to set the thickness of the support substrate to be larger than the thickness required for improving temperature characteristics.

In contrast, in the case where the pattern formation step is carried out before the substrate thickness reduction step, and the thickness of the piezoelectric substrate is reduced after the device pattern is formed on the piezoelectric substrate, warpage of the piezoelectric substrate due to heat during formation of the device pattern on the piezoelectric substrate can be reduced compared with the case where the device pattern is formed on the piezoelectric substrate, the thickness of which is reduced. Therefore, accurate patterning of the device pattern on the piezoelectric substrate can be easily performed. Furthermore, it is not necessary to set the thickness of the support substrate to be larger than the thickness required for improving temperature characteristics.

Preferably, the thickness of the adhesive layer after being cured is about 1 μm or less, and the Young's modulus of the adhesive layer after being cured is about 1 GPa or more, for example.

Usually, since a resin adhesive is soft, expansion and contraction of the piezoelectric substrate due to a change in temperature is absorbed by deformation of the adhesive layer, and the expansion and contraction of the piezoelectric substrate cannot be sufficiently suppressed by the support substrate. However, if the Young's modulus of the adhesive layer after being cured is about 1 GPa or more and if the thickness of the adhesive layer after being cured is about 1 μm or less, for example, the deformation of the adhesive layer decreases, and the expansion and contraction of the piezoelectric substrate can be sufficiently suppressed by the support substrate. Thus, it is possible to enhance the effect of improving temperature characteristics.

In addition, by roughening the other principal surface of the piezoelectric substrate before bonding, sufficient bonding strength can be obtained even if the thickness of the adhesive layer is about 1 μm or less, for example.

According to various preferred embodiments of the present invention, a surface acoustic wave device can be easily and efficiently manufactured with high accuracy.

Other features, elements, steps, characteristics and advantages of the present invention will become more apparent from the following detailed description of preferred embodiments of the present invention with reference to the attached drawings.

### BRIEF DESCRIPTION OF THE DRAWINGS

FIGS. 1A to 1D are cross-sectional views showing manufacturing steps of a surface acoustic wave device according to a preferred embodiment of the present invention.

FIG. 2 is a graph showing the relationship between the Young's modulus and coefficient of linear expansion of adhesive layer.

FIG. 3 is a graph showing the relationship between the thickness and coefficient of linear expansion of adhesive layer.

FIGS. 4A to 4D are cross-sectional views showing manufacturing steps of a conventional surface acoustic wave device.

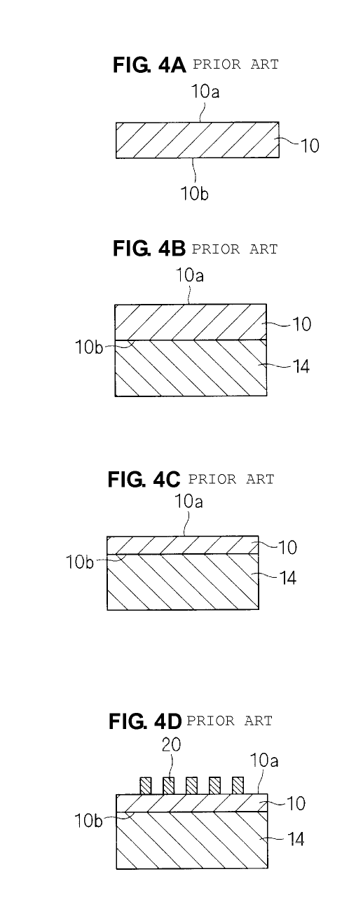

FIGS. 5A to 5C are cross-sectional views showing manufacturing steps of another conventional surface acoustic wave device.

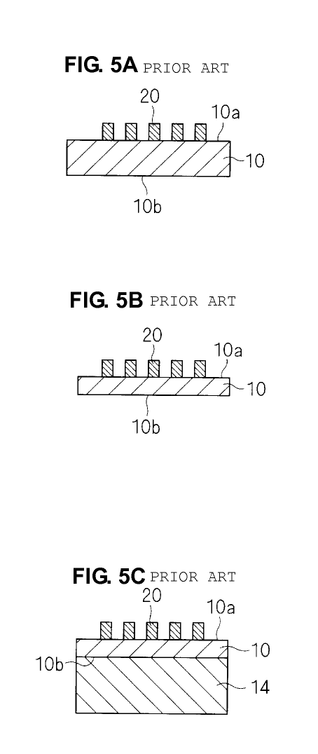

### DETAILED DESCRIPTION OF THE PREFERRED EMBODIMENTS

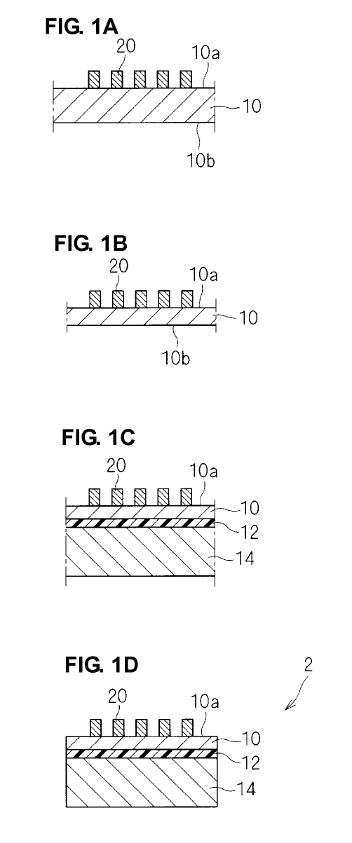

The preferred embodiments of the present invention will be described below with reference to FIGS. 1A to 3.

### Example 1

FIGS. 1A to 1D are cross-sectional views schematically showing a method for manufacturing a surface acoustic wave device 2 according to a preferred embodiment of the present invention. As shown in FIG. 1D, the surface acoustic wave device 2 includes a piezoelectric substrate 10, a support substrate 14 bonded through a resin adhesive layer 12 to a back surface 10b, which is a principal surface, of the piezoelectric substrate 10, and a device pattern 20 including IDT electrodes disposed on a front surface 10a, which is another principal surface, of the piezoelectric substrate 10.

A method for manufacturing the surface acoustic wave device 2 will now be described with reference to FIGS. 1A to 1D.

First, as shown in FIG. 1A, a device pattern 20 including IDT electrodes is formed on a front surface 10a of a wafer-shaped piezoelectric substrate 10.

Specifically, the device pattern 20 including IDT electrodes, pads (not shown), and wires (not shown) connecting between the IDT electrodes and pads is formed on the front surface 10a of the piezoelectric substrate 10, such as a lithium tantalate (LiTaO₃) substrate or a lithium niobate (LiNbO₃) substrate. The device pattern 20 is preferably formed by a method in which a metal film is formed on the front surface 10a of the piezoelectric substrate 10 by a thin-film deposition process, such as vapor deposition, sputtering, or CVD, and then the metal film is formed into a predetermined pattern using a photolithographic technique or an etching technique.

Next, as shown in FIG. 1B, the back surface 10b of the piezoelectric substrate 10 is machined to reduce the thickness of the piezoelectric substrate 10.

Specifically, with the front surface 10a of the piezoelectric substrate 10 being fixed through a joining material, such as a pressure-sensitive adhesive tape or wax, the back surface 10b of the piezoelectric substrate 10 is subjected to a removal process, such as grinding or lapping, to reduce the thickness of the piezoelectric substrate 10.

Since the piezoelectric substrate 10 is machined in a state in which the support substrate 14 is not bonded, in comparison with the case where the piezoelectric substrate 10 is machined while being supported by the support substrate 14 through an adhesive layer, variations in the thickness of the piezoelectric substrate 10 and waviness of the front surface are prevented from occurring, and the thickness of the piezoelectric substrate 10 can be reduced by machining with high accuracy. Furthermore, manufacturing can be performed efficiently in the wafer state.

Next, as shown in FIG. 1C, the support substrate 14 is bonded to the back surface 10b of the piezoelectric substrate 10 through the resin adhesive layer 12.

Specifically, in order to form a thin adhesive layer 12, an adhesive is applied by spin-coating. After the application, the adhesive may be spread to reduce the thickness of the adhesive layer 12 using a roller or the like.

When bonding is performed using the resin adhesive layer 12, the piezoelectric substrate and the support substrate can be bonded to each other at a lower temperature than the case where bonding is performed using a glass layer, and thus warpage due to heat can be reduced. For example, the adhesive layer 12 may be composed of a UV curable adhesive or a thermosetting adhesive. When a UV curable adhesive is used for the adhesive layer 12, the support substrate 14 can be bonded to the piezoelectric substrate 10 at room temperature, and it is possible to reliably prevent warpage and cracking of the wafer due to heat during bonding of the support substrate 14 to the piezoelectric substrate 10.

The support substrate 14 is formed using a material, such as Si, Al₂O₃, or SiO₂, which has a coefficient of linear expansion that is sufficiently smaller than the coefficient of linear expansion of the piezoelectric substrate 10 composed of lithium tantalate, lithium niobate, or the like. Because of the difference in the coefficient of linear expansion, expansion and contraction of the piezoelectric substrate 10 due to a change in temperature can be prevented by the support substrate 14, and variations in frequency characteristics of the surface acoustic wave device 2 can be prevented, thus improving temperature characteristics.

Next, after the joining material is removed by UV irradiation, chemical cleaning, or the like, the integrated body including the piezoelectric substrate 10, the adhesive layer 12, and the support substrate 14 is divided by dicing or the like. Thereby, a chip of surface acoustic wave device 2 shown in FIG. 1D is obtained.

In the manufacturing method described above, when the device pattern 20 including IDT electrodes is formed on the front surface 10a of the piezoelectric substrate 10, the thickness of the piezoelectric substrate 10 is not yet reduced, and the support substrate 14 is not bonded to the piezoelectric substrate 10. Therefore, it is possible to prevent warpage and wafer cracking due to heat in the pattern formation step.

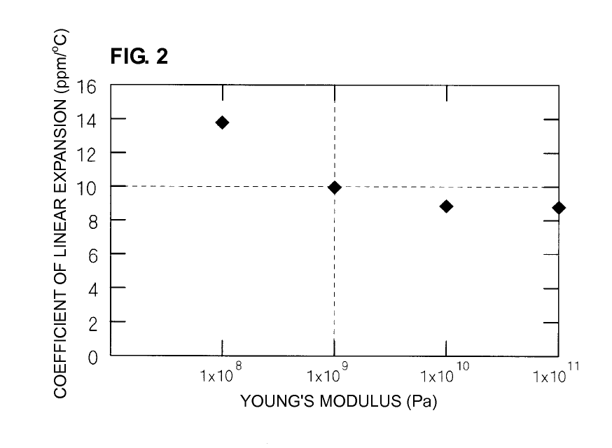

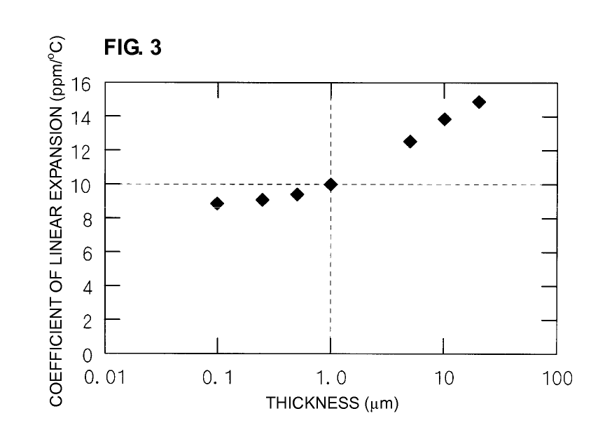

FIG. 2 is a graph showing the results of calculation of the coefficient of linear expansion of the front surface 10a of the piezoelectric substrate 10 when the Young's modulus of the adhesive layer is varied in the case where a lithium tantalate substrate is used as the piezoelectric substrate 10, and an adhesive layer 12 with a thickness of about 1 μm (after curing) is formed between the piezoelectric substrate 10 and the support substrate 14. FIG. 3 is a graph showing the results of calculation of the coefficient of linear expansion of the front surface 10a of the piezoelectric substrate 10 when the thickness of the adhesive layer is varied in the case where a lithium tantalate substrate is used as the piezoelectric substrate 10, and an adhesive layer having a Young's modulus of about 1 GPa, for example, is formed between the piezoelectric substrate 10 and the support substrate 14. When the coefficient of linear expansion is set to, for example, approximately 10 ppm/° C. or less, a large effect of improving temperature characteristics can be exerted. Consequently, as is evident from FIG. 2, it is preferable to set the Young's modulus of the adhesive layer (adhesive layer 12 after being cured) at about 1 GPa or more, and as is evident from FIG. 3, it is preferable to set the thickness of the adhesive layer (adhesive layer 12 after being cured) at about 1 μm or less, for example.

Usually, since a resin adhesive is soft, expansion and contraction of the piezoelectric substrate due to a change in temperature is absorbed by deformation of the adhesive layer, and the expansion and contraction of the piezoelectric substrate cannot be sufficiently prevented by the support substrate. However, if the Young's modulus of the adhesive layer after being cured is about 1 GPa or more and if the thickness of the adhesive layer after being cured is about 1 μm or less, for example, the deformation of the adhesive layer decreases, and the expansion and contraction of the piezoelectric substrate can be sufficiently prevented by the support substrate. Thus, it is possible to enhance the effect of improving temperature characteristics.

In addition, by roughening the back surface of the piezoelectric substrate before bonding in the substrate thickness reduction step, sufficient bonding strength can be obtained even if the thickness of the adhesive layer is about 1 μm or less, for example.

A method for manufacturing a surface acoustic wave device according to a modification example of the above preferred embodiments will be described.

In the modification example, the step of forming a device pattern on the front surface of the piezoelectric substrate is carried out after the thickness of the piezoelectric substrate is reduced and the support substrate is bonded to the piezoelectric substrate the thickness of which is reduced.

In the modification example, if the support substrate is thin, warpage may occur resulting from the difference in the coefficient of linear expansion between the piezoelectric substrate and the support substrate due to heat during formation of the device pattern on the piezoelectric substrate, thus preventing accurate patterning, and in the worst case, the wafer may be cracked. Therefore, it is preferable to set the thickness of the support substrate to be larger than the thickness required for improving temperature characteristics.

In contrast, as in Example 1, in the case where the thickness of the piezoelectric substrate is reduced after the device pattern is formed on the piezoelectric substrate, and the support substrate is bonded to the piezoelectric substrate the thickness of which is reduced, since the device pattern is formed on the piezoelectric substrate before its thickness is reduced, warpage of the piezoelectric substrate due to heat during formation of the device pattern can be reduced compared with the modification example in which the device pattern is formed on the piezoelectric substrate the thickness of which is reduced. Therefore, in Example 1, accurate patterning of the device pattern on the piezoelectric substrate can be easily performed compared with the modification example. Furthermore, in Example 1, it is not necessary to set the thickness of the support substrate to be larger than the thickness required for improving temperature characteristics.

As described above, by bonding a support substrate to a piezoelectric substrate using a resin adhesive layer after the thickness of the piezoelectric substrate is reduced, a surface acoustic wave device can be easily and efficiently manufactured with high accuracy.

While preferred embodiments of the invention have been described above, it is to be understood that variations and modifications will be apparent to those skilled in the art without departing from the scope and spirit of the invention. The scope of the invention, therefore, is to be determined solely by the following claims.

What is claimed is:

1. A method for manufacturing a surface acoustic wave device comprising:
a substrate thickness reduction step of reducing a thickness of a piezoelectric substrate by machining a principal surface of the piezoelectric substrate; and
a bonding step of bonding a support substrate having a smaller coefficient of linear expansion than the piezoelectric substrate through a resin adhesive layer to the piezoelectric substrate, which is reduced in thickness.

2. The method for manufacturing a surface acoustic wave device according to claim 1, further comprising, before the substrate thickness reduction step, a pattern formation step of forming a device pattern including at least one IDT electrode on another principal surface of the piezoelectric substrate.

3. The method for manufacturing a surface acoustic wave device according to claim 1, wherein the thickness of the adhesive layer after being cured is about 1 μm or less, and the Young's modulus of the adhesive layer after being cured is about 1 GPa or more.
